(19) United States
(12) Patent Application Publication
(10) Pub. No.: US 2014/0043122 A1
(43) Pub. Date: Feb. 13, 2014

(54) Magnetically Initiated Actuation Mechanism

(71) Applicants: John M. Birckhead, Houston, TX (US); Christopher W. Mayeu, Houston, TX (US)

(72) Inventors: John M. Birckhead, Houston, TX (US); Christopher W. Mayeu, Houston, TX (US)

(21) Appl. No.: 14/054,935

(22) Filed: Oct. 16, 2013

Related U.S. Application Data
(63) Continuation of application No. 13/447,657, filed on Apr. 16, 2012, now abandoned.
Application No. 13/447,657 is a continuation of application No. 13/224,771, filed on Sep. 2, 2011, now abandoned.
(60) Provisional application No. 61/379,653, filed on Sep. 2, 2010.

(51) Int. Cl. G01R 33/038

(52) U.S. Cl. CPC G01R 33/0385
USPC 335/219

(57) ABSTRACT

This invention relates generally to remote actuation of a device positioned in a borehole.

### BACKGROUND

The invention includes a series of electromagnetic sensors positioned in a tubing string. The electromagnetic sensors may be responsive to the polarity, strength or absence/presence of an external magnetic field. A second device containing permanent magnets or other means of generating a magnetic field is conveyed through the tubing containing the sensors. The magnets are arranged in sequence and spaced such that their relative position will become aligned with the sensors as the second device is conveyed through the tubing. When the second device passes through the tubing, the electromagnetic sensors detect their presence and the detection of this signal can initiate an actuator or start a timer for an action to be taken in the borehole.

In one embodiment in the figure below, the magnetic sensors 1 are placed in the wall of the tubing 2. The tubing wall may also contain sense electronics, a valve or other actuation device and/or a battery assembly (not shown). Conveyed device 3 has a series of circumferential magnets 4.

The conveyed device is lowered or pumped through the tubing.

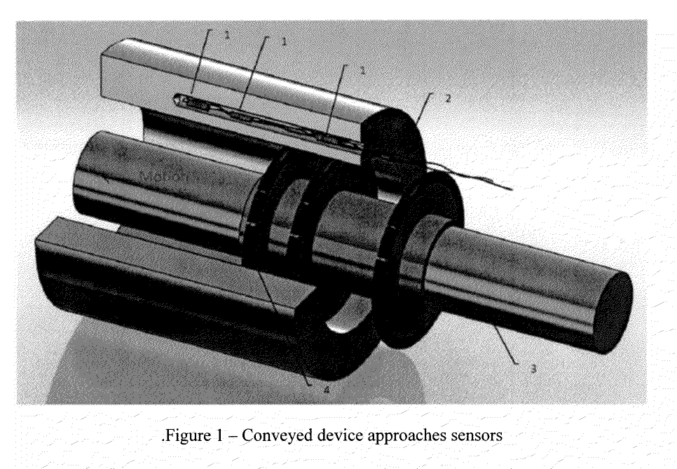

FIG. 1 shows the conveyed device 3 as it approaches the tubing section 2 containing the electromagnetic sensor array.

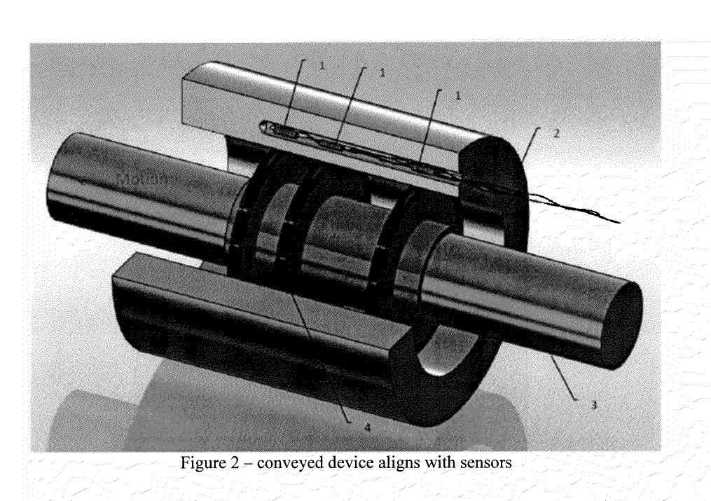

In FIG. 2, the conveyed device 3 has become moved to a point where the magnets 4 are aligned with magnetic sensors 1. When electronics 3 receive the response from with magnetic sensors 1, valve 4 is actuated, providing hydraulic energy to perform borehole tasks.

In practice, the invention may be used for common borehole actions such as shifting valves or sliding sleeves, and setting or releasing anchors or packers. The electronics may incorporate other sensors such as pressure, temperature, vibration or flow, and one or a combination of conditions may be required by the electronics to initiate actuation. The conveyed device may be dropped, lowered on a slickline, tubing conveyed, or attached to a plug or pig and pumped through the tubing. The actuator may trigger a hydrostatic valve, battery operated motor, explosive or incendiary device.

1. A magnetically initiated actuation mechanism, said mechanism comprising:
a first assembly comprising a plurality of electromagnetic sensors disposed within a tubular; and
a second assembly comprising a means for generating a magnetic field,
wherein said second assembly comprising a means for generating a magnetic field is conveyed through said tubular so that said sensors will detect either the presence or absence of said magnetic field, thereby initiating activation of an associated actuator.
